(19) United States
(12) Patent Application Publication
(10) Pub. No.: US 2026/0357463 A1
(43) Pub. Date: Nov. 12, 2026

(54) ELECTROPLATING APPARATUS AND METHOD FOR PRODUCING AN ELECTROPLATED COPPER FOIL USING THE SAME

(71) Applicants: CIRCUIT FOIL LUXEMBOURG, Wiltz (LU); Luxembourg Institute of Science and Technology, Esch-sur-Alzette (LU)

(72) Inventors: Rodolphe MAUCHAUFFÉ, Audun-Le-Tiche (FR); Patrick CHOQUET, Thionville (FR); Thomas DEVAHIF, Bastogne (BE); Alexandre LEMAIRE, Bovigny (BE); Julie MOUZON, Arlon (BE)

(21) Appl. No.: 19/489,756

(22) PCT Filed: Jun. 26, 2024
(86) PCT No.: PCT/EP2024/068021

§ 371 Date: Dec. 3, 2025

(30) Foreign Application Priority Data
Jun. 28, 2023 (LU) LU504597

(51) Int. Cl. C25D 1/04; C25D 17/12

(52) U.S. Cl. CPC C25D 1/04; C25D 17/12

(57) ABSTRACT

Methods for producing an electrolytic copper foil, comprising the steps of forming a copper foil in an electroplating cell comprising a tank with a copper electrolyte, a rotating cathode drum made of titanium or of a titanium alloy and an anode, wherein the copper foil is continuously formed on the cathode and removed therefrom, further comprising a treatment step, wherein a plasma jet is applied onto the exposed surface of the rotating cathode drum during production of the copper foil. Also, electroplating apparatus for performing such a method and comprising a metallic drum-shaped rotating cathode made of titanium or of a titanium alloy, a stationary anode, and a tank for an electrolyte wherein the cathode and the anode are arranged spaced apart from each other in the tank, and a plasma generating device.

### FIELD OF THE INVENTION

The present invention generally relates to the field of electrodeposited copper foils and more specifically to an apparatus and method to produce electrodeposited copper foils. The invention particularly addresses the treatment of hydride corrosion, which may form during electroplating.

### BACKGROUND OF THE INVENTION

The process and production of electrodeposited (or electrolytic) copper foils is basically a plating technique, as it involves arranging two electrodes (a cathode and an anode) in an electrolyte containing a copper salt, passing current between the electrodes and depositing copper on the cathode with a desired thickness. The electrodeposited copper foil is then peeled off from the surface of the cathode, and coiled onto a storage reel. The cathode is generally a rotating drum-shaped cathode and is arranged in the electrolyte to face a stationary anode.

The side of the electrolytic copper foil contacting the surface of the drum is referred to as the shiny or drum side, and the opposite side of the copper foil is referred to as the matte or electrolyte side. The surface aspect, and in particular the surface roughness, of the matte side can be controlled by adjusting the composition of the electrolyte while the surface roughness of the shiny side reflects the surface of the drum-shaped cathode. Defects such as local increased rugosity of the surface of the drum therefore strongly impact the quality of the produced electroplated copper foil.

Over the past decades, drum-shaped cathodes made of titanium have been developed, as this metal is relatively stable in acidic solutions, such as copper sulfate solutions used as electrolytes for the production of electroplated copper foils. Moreover, titanium drums are lighter than drums made of stainless steel and therefore easier to handle.

Unfortunately, after a certain time a brownish titanium hydride layer is forming on the titanium drum, leading to increased roughness of the drum surface which is reflected on the shiny side of the produced copper foils and thus leads to the deposition of lower quality copper foils.

Currently, the most common method used to limit the formation of the layer is polishing: the titanium drum surface is polished with a brush at regular intervals, during a production stop. Such on-site polishing methods are disclosed e.g. in patent application JPH 10-330984 A.

However, when the on-site polishing is no longer sufficient to maintain a good drum surface state, the drum is removed for off-site fine polishing of its surface in order to restore suitable surface properties, in particular a suitable surface roughness, thus temporarily stopping the copper foil production. Moreover, the polishing leads to the reduction of the thickness of the titanium drum, shortening its lifespan.

Another solution is disclosed in US 2003/116241 A1. This patent application proposes to manufacture titanium drum-shaped cathodes with a lower hydrogen content to delay the growth of the original hydride layer, in order to require less polishing. This approach however involves fully replacing the drum to limit the problem, which represents an important investment, and does not fully prevent but only delays the formation of the hydride layer.

JP2003328177A in turn suggests improving the lifetime of a cathode electrode by coating the latter with a ceramic layer of titanium nitride (TN) layer or chromium nitride (CrN). This ceramic coating is formed before installation of the cathode in the electrolysis cell. This document recommends the use of cathode made of stainless steel to avoid hydride corrosion issues. Further, to form the ceramic layer, it is recommended to use the hollow cathode ion plating method as the most stable method for forming a droplet-free ceramic layer. In contrast, the arc plasma ion plating method is said to be less desirable in that when the constituent materials evaporate from the target, some spots on the target surface reach extremely high temperatures of over 5000 K, causing instantaneous evaporation from those areas, resulting in a splash phenomenon in which the material turns into droplets and scatters, and the spherical titanium adheres to the surface of the formed ceramic layer as droplets.

Finally, CN 115 360 357 A addresses safety performance of the lithium ion secondary cycle life battery. For improved safety, it is proposed to use a negative electrode and negative electrode current collector copper foil for, in which silicon active material is physically embedded in the copper foil during the production process of the electrolytic copper foil. Specifically, a method is disclosed where first a silicon nanowire powder or suspension is prepared, and the powder/suspension is blown by a plasma wind onto the free surface of the cathode drum, upon which the electrolytic copper foil is then formed. Thereby, the silicon nanowires are embedded in the copper foil surface.

### OBJECT OF THE INVENTION

It is an object of the present invention to provide a solution to maintain the surface of a cathode drum in an electrolytic cell, which increase the lifespan of the cathode and minimizes production outages.

### SUMMARY OF THE INVENTION

According to the present invention, a method for producing an electrolytic copper foil comprises the step of forming a copper foil in an electroplating cell comprising a tank with a copper electrolyte, a rotating cathode drum and an anode, wherein the copper foil is continuously formed on the cathode and removed therefrom and wherein the cathode is made of titanium or of a titanium alloy. According to the invention, the method further comprises performing an anti-hydride treatment step wherein an atmospheric plasma jet is applied onto the exposed surface of the rotating cathode drum during the production of the copper foil.

According to another aspect, the present invention provides an electroplating apparatus, in particular configured for carrying out (i.e. performing) the method according to the first aspect as disclosed above.

The electroplating apparatus comprises:
a metallic drum-shaped rotating cathode made of titanium or of a titanium alloy,
a stationary anode;
a tank for an electrolyte, wherein the drum-shaped cathode and the anode are arranged spaced apart from each other in the tank; and
a plasma generating device configured to generate an atmospheric plasma in a plasma chamber, the plasma chamber having an outlet facing the drum-shaped cathode such that a plasma jet irradiates at least a portion of a surface of the drum-shaped cathode to treat the latter against hydride corrosion.

Technical features, explanations and advantages disclosed in relation to the herein disclosed method for producing an electrolytic copper foil apply mutatis mutandis to the present electroplating apparatus, and conversely.

As will be understood, the term “exposed surface” refers to the portion of the cathode drum surface that is not immersed in the electrolyte and that is not covered by copper, as the copper foil is being continuously removed/peeled from the cathode drum.

In the present text, “atmospheric plasma generating device” refers to a plasma generating device operating in an atmospheric, open-air environment (i.e. under atmospheric pressure). In other words, an atmospheric plasma generating device is a system designed to produce plasma at atmospheric pressure, as opposed to requiring the vacuum conditions typically associated with plasma generation. Accordingly, in the present text, an “atmospheric plasma jet” flows through the air at atmospheric pressure.

The present invention proposes a method for producing an electrolytic copper foil, and a correspond electroplating apparatus, that—according to first results—enables treating the surface of the drum-shaped rotating cathode against hydrogen corrosion, which typically occurs due to the formation of a hydride layer on the cathode drum during electrolysis. Particularly, such plasma treatment allows limiting the formation of titanium hydride formed during electrodeposition of copper thereon, and also delaying the growth of such an hydride layer. In other words, the invention applies the plasma jet, correspondingly uses the plasma generating device, to provide a surface treatment to the rotating cathode drum, which can be referred as “anti-hydrogen corrosion treatment” or ‘anti-hydride formation treatment’.

Surprisingly, the inventors found out that by using an atmospheric pressure plasma technology in order to treat the surface of the titanium drum during production of the copper foil, they were able to delay and/or limit the formation of a metal hydride layer, such as a titanium hydride layer, on the surface of the metallic drum during copper foil formation but also to remove an already formed (spontaneously grown, i.e. not intentionally formed but appeared as by-product during use of the metallic drum) metal hydride layer. Indeed, interactions of the plasma jet with the surface of the drum advantageously leads to the removal of the formed layer of titanium hydride without physical (such as e.g. mechanical) contact. Moreover, interactions of the plasma jet with the surface of a new and clean metallic drum-shaped cathode generates a plasma-induced film able to delay and/or limit the growth of a metal hydride layer. Without willing to be bound by any theory, the inventors are of the opinion that the formation of the hydride layer is delayed due to the formation of a metal oxide layer (typically titanium oxide for a titanium drum) on the surface of the new, clean metallic drum upon irradiation thereof by the plasma jet.

By formation of a metal oxide layer, the inventors refer to the modification of the surface of the titanium-containing drum, i.e. titanium at the surface of the drum may react with species of the plasma jet and oxidize to form a metal oxide layer. There is however no deposition of new material, respectively coating of any layer of material, onto the surface of the drum, as there is e.g. no providing of metallic element to form the metal oxide layer (the metal being provided solely by the drum shaped cathode itself). In other words, the formation of the metal oxide layer changes composition of the surface of the rotating cathode drum without changing its dimensions, in particular there is no increase of the diameter of the drum.

In other words, the anti-hydride treatment step is not a deposition process, in particular does not deposit new particles or metal elements, in particular to form a ceramic layer. In contrast, the anti-hydride treatment step is rather a Surface Modification Processes, in the sense that it involves altering the properties of the cathode drum surface without adding new material on top of it. In particular, the process includes cleaning, and/or chemical modification. In particular, chemical modification involves oxidation by incorporation of oxygen from the plasma into the substrate's surface.

It may be noted that the plasma jet used in the invention (as emitted by the plasma generating device) is preferably not formed from, resp. does not contain, titanium, and more specifically not formed from metal elements. That is, the plasma jet is not generated using metal precursors.

In the present text, ‘hydride corrosion’ or ‘hydrogen corrosion’ refers to the formation of stable metal-hydride phases on metallic surfaces due to exposure to hydrogen, in particular to metal hydride layers, which may be continuous or not.

Moreover, the plasma jet is applied, respectively the plasma generating device is used, to provide surface treatment on the rotating cathode drum, during the electroplating process, hence without stopping the production.

One of the merits of the invention is thus that such a method for producing an electrolytic copper foil, and electroplating apparatus, allows the treatment of the drum-shaped cathode during production of an electrodeposited copper foil, i.e. there is no need to stop the production of copper foils in order to treat the cathode. Moreover, a hydride layer on the drum-shaped cathode may be removed without the need to resort to mechanical methods likely to cause a reduction of its thickness, such as e.g. polishing of the surface, thereby increasing the lifespan of the drum.

Another merit of the invention is that the plasma generating device operates in an atmospheric, open-air environment and can thus be implemented on any existing electroplating cell comprising a cathode, an anode and a tank for an electrolyte. Industrial installations for production of electrodeposited copper foils may thus easily be turned into the present electroplating apparatus by the fitting of a plasma generating device having a plasma chamber with an outlet facing the drum-shaped cathode, and any known process to produce an electrolytic copper foil may be converted into the present method by applying a plasma jet onto the exposed surface of the cathode during production of the copper foil.

Still another merit of the invention is that the use of a properly controlled plasma treatment will not deteriorate the surface roughness of the cathode drum, contrary to brush treatments.

Yet another merit of the present invention is that the treatment of the surface of the rotating cathode drum does not negatively impact production of the electrolytic copper foil, in particular it does neither slow down nor prevent formation of the copper foil. Surprisingly, the inventors found out that copper foils produced by the present inventive method, i.e. comprising a step of treating the drum during production of the copper foils, may be removed from the drum as easily as copper foils produced according to a conventional method, and do not present more visual defects, such as e.g. tears, wrinkles, craters and/or overgrowth defects.

In summary, the invention has found a solution to address the formation of hydride(s) on the metallic drum-shaped cathode made of titanium or of a titanium alloy. The proposed plasma treatment has been found capable of (i) removing a hydrogen corrosion layer formed on the cathode, such as a hydride layer, and also of (ii) delaying/limiting the growth of such a hydride layer during the production of an electrodeposited copper foil. This treatment can be applied without having to stop the copper foils production in order to treat the drum, i.e. can be applied during production of the copper foils, without negatively affecting produced copper foils.

Moreover, due to the flow of process gas into a plasma chamber, a blown arc plasma (i.e. plasma jet) is formed, which irradiates the surface of the cathode drum. The plasma generating device is configured to allow for the formation of micro-arcs (in some cases called pseudo arcs) having high electronic densities and electron temperature (Te) substantially higher than the temperature of the other species (ions, . . . ) and between 4000 and 11000 K, preferably between 6500 and 9000 K. Blowing this hot arc, a plasma jet is obtained at the output of the plasma chamber with high gas temperatures. The gas temperature of the plasma jet (and/or the electron temperature) may be controlled by adapting one or more of the following parameters: composition of the process gas; process gas flow rate; electric power; frequency of the plasma discharge and distance output of chamber to the surface of the cathode. That is to say, according to the present invention, the plasma jet has an electron temperature comprised between 4000 and 11000 K, preferably between 6500 and 9000 K. This may typically be the electron temperature in the plasma chamber. In the vicinity of the cathode drum, the plasma jet may typically have a gas temperature comprised between 400 and 1100 K, preferably between 500 and 800 K.

First tests have shown that such plasma temperatures are particularly adapted for the treatment of hydrogen corrosion in optimal conditions. Tests with plasma jets having a comparatively lower electron and/or gas temperature were, in certain conditions, not successful, i.e. the treatment did not permit entirely removing hydride layers nor delay the formation thereof. Tests with plasma jets having a higher electron and/or gas temperature tend to induce local modifications of the surface of the cathode drum (such as e.g. local fusion phenomena) which alter the surface roughness of the cathode, and is not desirable as it will deteriorate the surface roughness of a produced copper foil. For example, a plasma technology commercialized by the company AcXys Technologies (France) may be used, however any other plasma technology enabling the production of an atmospheric plasma having an electron temperature between 4000 and 11000 K, preferably between 6500 and 9000 K, and a gas temperature between 400 and 1100 K, preferably between 500 and 800 K may be used.

The rotating cathode drum (i.e. drum-shaped cathode) is made of titanium or of a titanium alloy, as may be conventional when the electroplating apparatus is used in the copper plating industry, i.e. for manufacturing electrolytic copper foils. In such case the electrolyte in the tank is typically an acid solution of copper cations. A drum shaped cathode used in the method according to the present invention may typically have a cylindrical outer layer defining the deposition surface (drum side) made from titanium or titanium alloy. In particular, the cylindrical outer layer may be a sheet of titanium or titanium alloy, that is arranged on a cylindrical support structure.

Preferably, the metal sheet forming the outer layer of the cathode drum an unalloyed titanium sheet. Specifically, the titanium content is at least 99.5 wt. %. The maximum admissible content for impurities is, expressed in wt. %: Carbon:
0.015; Hydrogen: 0.005; Oxygen: 0.09; Nitrogen: 0.01; Iron: 0.05.

Preferred mechanical properties:
Yield Strength: at least 25000 psi (170 MPa)
Tensile Strength: at least 35000 psi (240 MPa)
Elongation: at least 25%
Hardness: 70-80 Rockwell B.

In particular, the unalloyed titanium sheet may be of the grade 1 type.

More preferably, the titanium foil consists of Equiaxed and uniform ASTM alpha grain size 9±1.

Advantageously, the titanium sheet has no seam/no grain difference due to seam; is hot worked and fully annealed; and free of void, macro and micro porosities, cracks, inclusions, ghost or dendrite pattern.

In embodiments, the metal sheet forming the outer layer of the cathode drum is made from a titanium alloy. Such titanium alloy comprises at least 90.0% of Ti. For example, possible titanium alloys are Ti-6Al-4V, or Ti-0.2Pd.

In the present text, the expressions “drum-shaped cathode”, “cathode”, “drum”, and “rotating cathode drum” are used as synonyms and refers to the same physical object, namely a cathode of an electroplating apparatus.

In embodiments, the plasma jet is configured to irradiate (only) a portion of the exposed surface of the drum-shaped cathode at a time, namely a part of the exposed portion (i.e. non-immersed), i.e. the plasma generating device is not configured to generate a plasma jet irradiating simultaneously the whole exposed surface of the drum-shaped cathode. Advantageously, in use, such embodiments allow to temporally limit the irradiation of each portion of the surface of the cathode. Each portion of the exposed surface is not continuously irradiated by the plasma jet, so that there is no substantial heating of the surface of the drum-shaped cathode, even in embodiments wherein the plasma generating device is configured to be continuously on during use of the electroplating apparatus, as the cathode rotates around its axis. The (relative) time during which each portion/spot of the surface of the cathode is irradiated depends on various process parameters, such as e.g. size of the plasma jet, on-time of the plasma generating device, dimensions of the cathode, and rotation speed of the cathode, and may be comprised between 0.1% and 40% of the time, preferably between 0.1 and 10% of the time, more preferably between 0.1 and 1% of the time, even more preferably between 0.2 and 0.5% of the time—i.e. per cathode revolution.

In the present text, ‘no substantial heating’ means that, while the surface of the drum-shaped cathode might be locally heated due to the application of the plasma jet, the average temperature of the cathode does not increase and electroplating deposition parameters such as e.g. current density or cathode rotating speed, do not need to be adapted compared to conventional practice. Preferably, during the anti-hydride treatment step the local surface temperature of the cathode drum, i.e. where the plasma jet is applied, does not exceed 200 °C.

The portion of the cathode drum surface that is contacted, and hence treated, by the plasma jet is referred to as ‘treatment area’ (or ‘treated area’ or ‘treated surface’). Its configuration and shape depend on the design of the plasma treating device, respectively of the plasma chamber.

Since the ‘treated surface’ represents a portion of the cathode surface, relative movement is required between both such that the entire cathode surface can be treated. Relative movement may be performed at a speed comprised between 3 mm/s and 10 cm/s.

In the context of an electroplating cell with a rotating cathode drum, the idea is to treat the exposed (i.e. non-immersed) surface of the cathode, which changes as the cathode rotates. Different configurations can be envisaged. For example, according to some embodiments, the plasma generating device can be designed to be fixed, so that the treated area changes as the cathode rotates. In other words, in such embodiments, plasma jet is generated by a plasma jet generating device which is fixedly mounted with respect to the electroplating cell, in particular to the tank/anode.

In such case, the plasma generating device may comprise a chamber configured to, respectively the plasma chamber may be configured to, treat a strip of surface that extends along the direction of the cathode axis. The plasma chamber may be configured to extend over the whole length of the cathode, in order to project a coherent/continuous blade or curtain of plasma jet.

Alternatively, the plasma (jet) generating device may comprise an array of plasma chambers, the latter being arranged to project respective plasma jets over the length of the cathode, or part thereof depending on the desired treatment area. According to such embodiments, the plasma chambers of the array of plasma chambers are arranged and configured to produce partially overlapping plasma jets, hence producing a continuous curtain/blade of plasma jet, over the treatment area. The plasma chambers of the array may be substantially identical to one another or they may be of different design. In particular, all plasma chambers may be configured to project a plasma jet having a length, along the direction of the cathode axis, of a few centimeters, such as e.g. between 1 and 10 cm, preferably between 2 and 8 cm, more preferably of about 5 cm. In such embodiments, the number and arrangement of the plasma chambers is determined so that the resulting curtain of plasma jet, generated by the array of plasma chambers, irradiates the whole treatment area, i.e. desired portion (length, width) of the cathode.

In other embodiments, the plasma generating device may be configured to produce a plasma jet over a treatment area that has a dimension that represents a fraction of the cathode length. In such case the plasma generating device can be moved, e.g. by means of a robot arm, relative to the rotating cathode drum, in such a way as to perform a scanning of the drum surface. In other words, in embodiments, the plasma jet may be generated by a plasma generating device mounted on a mobile support configured to move the plasma generating device relative to the cathode and the plasma jet may be continuously scanned over the exposed surface of the cathode drum. That is to say, the plasma chamber of the plasma generating device may be mounted on a support configured to move the plasma chamber relative to the drum-shaped cathode.

For example, the plasma generating device may be mounted on an industrial robot arm configured to move the plasma generating device with respect to the exposed surface of the cathode. In particular, when the cathode is rotating during electroplating of a foil such as e.g. a copper foil, the robot arm is configured to move the plasma device in order to scan the non-immersed area of the cathode drum.

In particular, the plasma chamber with its outlet for the plasma jet may be moved along the direction of the axis of the rotating drum-shaped cathode, so that the plasma jet exiting the outlet of the plasma chamber on the robot arm may be continuously scanned over the exposed surface of the cathode drum. In doing so, the robot arm is advantageously configured to move the plasma chamber with respect to the surface of the cathode following such a pattern that each portion of the surface of the cathode is submitted to the plasma jet at least once on every rotation of the cathode.

The scanning movement of the plasma generating device is configured such that the whole cathode surface can be treated after e.g. one revolution, or more. The on-time of the plasma generating device may depend on the circumstances, and in particular on growth kinetics of the hydride layer. In embodiments, the plasma generating device may be always on during production. In other embodiments, the plasma generating device is operated according to a predetermined duty-cycle, i.e. it is on for a certain percentage of a reference time period, and off for the rest of the reference time period.

In other words, in embodiments, the plasma jet is continuously applied onto the exposed surface of the rotating cathode drum during the production of the copper foil. Alternatively, the plasma jet may be periodically applied onto the exposed surface of the rotating cathode drum. For example, the plasma generating device may be turned on about between 50 and 75% of the production time, i.e. the plasma jet may be applied onto the exposed surface of the cathode drum during about between 50 and 75 % of production time.

In embodiments, the plasma generating device comprises a process gas inlet into the plasma chamber and at least one pair of electrodes to create a discharge therebetween, thereby producing the plasma jet.

In preferred embodiments, a plasma jet is generated under atmospheric pressure in a plasma chamber where the distance between the electrodes of the at least one pair of electrodes is a few millimeters, typically between 1 and 5 mm.

The plasma jet may be generated by a discharge being generated with a total power of a few kilowatts, such as e.g. 25000 to 75000 W, preferably 35000 to 65000 W, more preferably 40000 to 60000 W, even more preferably 50000 W for a plasma, however, such a power might be adapted depending on the process parameter when using the present electroplating apparatus, such as but without being limited to, the type of the electrolyte in the tank, the rotating speed of the cathode and the current density applied between the cathode and the anode of the electroplating apparatus. Such total power is considered adapted for treating a conventional titanium cathode drum having a diameter of about 2 to 3 m, in particular between 2.2 and 2.7 m, and a length (along central axis) of about 1.5 to 2 m.

In embodiments wherein the plasma generating device comprises an array of plasma chambers, the discharge in each one of the plasma chambers may be generated with a power of a few hundred watts, such as e.g. 500 to 1500 W. Such plasma chamber allows producing a jet having a width between 5 and 50 mm.

In embodiments, the plasma generating device is designed as a plasma torch. The process gas may be any gas adapted to produce a plasma under atmospheric pressure and provide the desired anti-hydrogen corrosion (anti-hydride) treatment with desired efficiency.

Preferably, the plasma jet is generated by an atmospheric plasma generating device (i.e. working under atmospheric pressure) from a process gas comprising at least 60 %-vol of nitrogen, preferably at least 70%-vol. or 75%-vol of nitrogen. More preferably, the process gas is air, preferably supplied with a flow rate in a range between 1 to 1000 L/min, preferably between 1 and 100 L/min, more preferably between 1 and 50 L/min to the plasma generating device.

In other words, the process gas preferably comprises at least 60 %-vol of nitrogen, more preferably at least 70%-vol. or 75%-vol of nitrogen. In embodiments the process gas is air, preferably compressed air. The use of air and/or nitrogen has proven particularly effective for the treatment of titanium cathodes.

In such case, the plasma jet comprises species such as, but without being limited to, reactive species such as metastable nitrogen and/or oxygen free radicals and/or ultraviolet photons.

Preferably, the plasma jet comprises species like nitrogen oxides (NOx) and hydroxyl radicals.

Without willing to be bound by any theory, the inventors are of the opinion that the reactive species in the plasma jet chemically react and wipe out the hydride layer. Moreover, the presence of reactive oxygen-containing species may also react with the surface of the cathode to oxide the latter, thereby inducing the formation of a very thin oxide layer.

As mentioned above, formation of the oxide layer occurs by chemical modification of the surface of the drum shaped cathode; there is no deposition/coating of an additional layer, in particular there is no addition/inflow of metal to form the metal oxide of said layer.

In embodiments wherein the plasma jet is generated from a flow of nitrogen, and as the plasma jet travels through open-air from the plasma generating chamber toward the surface of the cathode, energy of the plasma jet may be sufficient to activate oxygen in ambient air which can be incorporated in the plasma and reactive (e.g. metastable) oxygen species can be formed, inducing oxidation of the surface of the cathode.

In embodiments, a distance between the outlet of the plasma generating device (through which the plasma jet is ejected) and the (exposed) surface of the cathode drum depends on the operative parameters of both the plasma generating device (such as e.g. the type, pressure and flow rate of the gas) and the electroplating cell (such as e.g. the type of the electrolyte, the applied current density and rotating speed of the cathode), but also on structural constraints of the electroplating cell formed by the cathode, the anode and the tank. However, in practice, the distance preferably corresponds to a few centimeters, such as e.g. between 1 and 20 cm, preferably between 1 and 15 cm, more preferably between 1 and 5 cm, even more preferably between 1 and 3 cm, and most preferably between 1 and 2 cm.

The rotating drum-shaped cathode is preferably irradiated by the plasma jet substantially over its whole length along its rotation axis, so that the treatment area of the cathode, which is irradiated by the plasma jet, has a length along the direction of the cathode axis of at least 90% of the length of the cathode, preferably at least 95% and more preferably 99% to 100%. The treatment area may have a width along a tangential direction relative to the cathode surface, lying between 1 and 10 cm, preferably between 1 and 5 cm, e.g. of about 2 or 3 cm.

According to yet another aspect, the invention also relates to the use of an atmospheric plasma generating device to remove and/or prevent formation of a hydride layer on a metallic cathode made of titanium or of a titanium alloy, wherein a surface of the metallic cathode is irradiated in an open-air environment with a plasma jet produced by the plasma generating device. In preferred embodiments, an electroplating apparatus as disclosed herein is used in a method for producing an electrolytic copper foil as disclosed herein in order to remove a hydride layer, formed onto the metallic rotating drum-shaped cathode.

Technical features, explanations and advantages disclosed in relation to the herein disclosed method for producing an electrolytic copper foil apply mutatis mutandis to the present use of an atmospheric plasma generating device to remove and/or prevent formation of a hydride layer on a metallic cathode. In particular, all features such as gas composition, gas flow, temperature, (absence or speed of) relative movement between plasma generating device and cathode, etc. mentioned in relation to the inventive method applies to the presently disclosed used of an atmospheric plasma generating device.

In the present text, the expressions drum-shaped cathode, cathode, and cathode drum are synonyms to one another and may be employed independently from one another while referring to the same object, namely the drum-shaped rotating cathode of an electroplating apparatus or an electroplating cell.

In the present text, the term layer refers as well to continuous layer as to discontinuous layers. In the sense of the present invention a hydride layer may consist of metallic hydride or comprise metallic hydrides and other components/compounds, such as e.g. metal or metallic oxides. Similarly, in the sense of the present invention an oxide layer may consist of metallic oxide or comprise metallic oxides and other components such as e.g. metal or metallic hydrides.

Further details and advantages of the present invention will be apparent from the following detailed description of several not limiting embodiments with reference to the attached drawings.

### BRIEF DESCRIPTION OF THE DRAWINGS

The present invention will now be described, by way of example, with reference to the accompanying drawings, in which:

FIG. 1: is a principle drawing of an apparatus according to an embodiment of the invention;

FIG. 2: is a principle drawing illustrating the position of the plasma generating device relative to the cathode drum in FIG. 1;

FIG. 3: is a X-ray diffractogram of a hydride layer formed on the surface of a titanium cathode;

FIG. 4: is a graph representing the sputtering time required during ToF-SIMS depth profiling to reach the titanium substrate for a reference titanium substrate, a titanium substrate with a titanium hydride layer, the titanium substrate with the hydride layer after treatment according to a first embodiment of the invention and the titanium substrate with the hydride layer after treatment according to a second embodiment of the invention;

FIG. 5: are X-ray photoelectron spectra of a) a reference titanium substrate and b) the substrate of a) after treatment with plasma jet;

FIG. 6: is a graph representing the sputtering time required during ToF-SIMS depth profiling to reach the titanium substrate as a function of the growth duration of the titanium hydride layer for a) a reference titanium substrate and b) a titanium substrate treated according to the invention; and

FIG. 7: is a principle drawing of another configuration of the plasma generating device.

### DETAILED DESCRIPTION OF PREFERRED EMBODIMENTS

The present invention addresses issues specific to copper foils production by electrodeposition. Specifically, the invention provides, in the following description, embodiments of apparatuses and methods to produce electrodeposited copper foils providing improved lifespan of metallic drum-shaped cathode and reduced deposition of bad quality copper foils. According to the invention, the herein disclosed apparatus or process use an atmospheric plasma generating device to treat an exposed (non-immersed) surface of the rotating cathode, which has been found to allow removing of hydrides formed onto the surface of the cathode during the copper electrodeposition in the electrolytic cell, as well as formation of a layer of oxides onto the surface of the cathode, which tends to delay the growth of hydride layer.

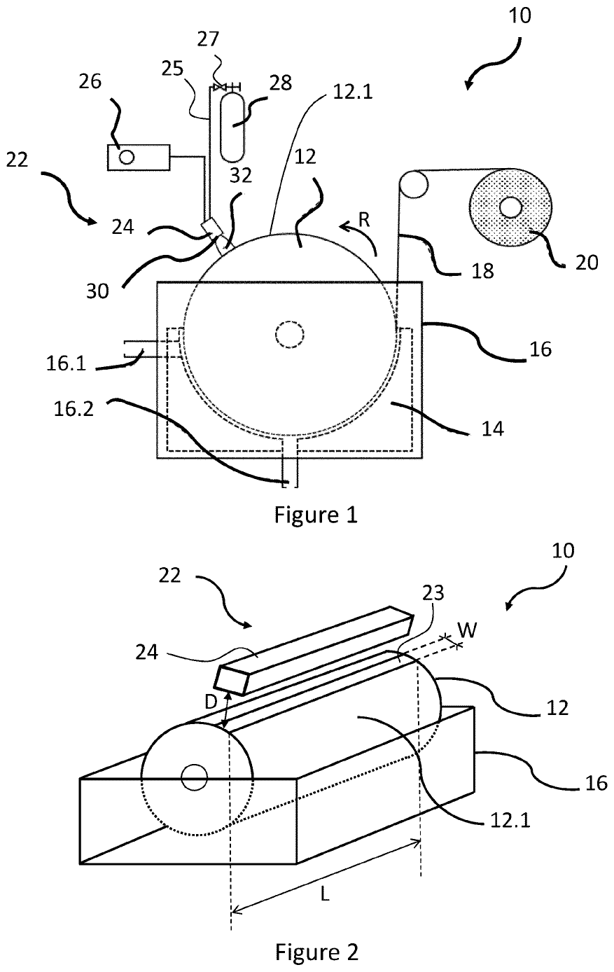

FIG. 1 schematically illustrates an electroplating apparatus according to an embodiment of the present invention. It includes a metallic drum-shaped cathode 12, in particular a titanium drum-shaped cathode, a stationary anode 14, such as e.g. a lead or a titanium electrode covered by a precious metal oxide, and a tank 16 for an electrolyte, which may flow from a tank inlet 16.1 toward a tank outlet 16.2. In production, the drum-shaped cathode 12 is rotating and is arranged in the tank 16 to face the stationary anode 14. The cathode 12 and the anode 14 are spaced apart from each other. The anode 14, the cathode 12 and the tank 16 form an electroplating cell.

As is known in the art, the electrolyte is typically an acid copper sulfate bath comprising copper sulfate and sulfuric acid as primary constituents. The formulation of the bath is adjusted depending on the intended use; typically copper and sulfuric acid concentrations may be above 60 g/L. Additives may be conventionally used to control properties such as e.g. tensile strength, elongation, roughness, bonding force, etc. The composition of the electrolyte is not the focus of the invention and hence will not be further detailed.

To produce an electrodeposited copper foil, the tank is filled with such an electrolyte and an electric current is passed through both electrodes 12, 14 to deposit copper on the outer cylindrical surface 12.1 of the cathode 12. At the same time the cathode 12 is rotating (see arrow R), whereby the deposited layer progressively grows on the drum surface, until a layer with a desired thickness is obtained, thus forming an electrodeposited copper foil 18. The electrodeposited copper foil 18 is then peeled off (detached/separated) from the surface of the cathode 12 and coiled onto a storage reel 20.

It will be appreciated that the apparatus further comprises at least one plasma generating device 22 configured to generate an atmospheric plasma (or plasma discharge) in a plasma chamber 24.

The plasma generating device 22 is operatively connected to a power supply 26 and a process gas source 28, respectively configured to supply power and process gas to sustain plasma formation in the plasma chamber.

The plasma chamber 24 comprises a process gas inlet in fluidic connection with the process gas source 28, a pair of electrodes operatively connected to the power supply 26 and configured to generate a power discharge therebetween, and a plasma jet outlet 30. The plasma jet outlet 30 faces the cathode 12 such that a plasma jet 32 generated by the plasma generating device 22 in the plasma chamber 24 and exiting through the outlet 30 irradiates at least a portion of the surface 12.1 of the drum-shaped cathode 12.

The power supply 26 may be any kind of a high voltage generator, a direct current constant current power supply and an alternative current constant current power supply, supplying a substantially constant power to the electrodes of the plasma chamber 24.

The process gas source 28 here delivers a stream of compressed air and/or compressed nitrogen, from a bottle or through a compressor, which flows towards the plasma chamber 24 of the plasma generating device 22. As illustrated in FIG. 1, process gas source 28 is here a bottle connected through an appropriate supply pipe 25 to the plasma chamber. A regulator valve 27 allows controlling the flow discharged from bottle 28.

The plasma generating device 22 is arranged above the drum-shaped cathode 12, i.e. opposite the tank 16, such that the plasma jet outlet 30 of the plasma chamber 24 faces a region of the drum-shaped cathode 12 which is not immerged in the tank 16.

Advantageously, the plasma generating device 22 is arranged with respect to the drum-shaped cathode 12 in such manner that the outlet 30 of the plasma chamber 24 faces a portion of the cathode 12 opposite from the region where the electrodeposited copper foil 18 is peeled/separated from the cathode 12 and coiled onto the storage reel 20.

In other words, the plasma generating device 22 is arranged with respect to the drum-shaped cathode 12 such that, in use, the plasma jet 32 generated in the plasma chamber 24 and exiting therefrom through the plasma jet outlet 30 irradiates a portion of the surface 12.1 of the cathode 12 which is neither immerged in the tank 16 nor covered by the electrodeposited copper foil 18. The plasma jet outlet 30 of the plasma chamber 24 of the plasma generating device 22 faces a free portion of the surface of the cathode, i.e. the plasma irradiated surface of the cathode is directly irradiated by the plasma, without physical intermediate (apart from ambient air) between the plasma jet outlet 30 and the surface 12.1 of the cathode 12.

The surface of the cathode 12 that is exposed to the plasma jet and hence treated is referred to as ‘treatment area’, ‘treated area’ or ‘treatment surface’. The plasma chamber is configured, dimensioned and positioned to produce a plasma jet that matches the treatment area.

### Detailed Embodiment of the Plasma Generating Device

According to a preferred but non-limiting embodiment, the plasma generating device 22 is configured as an atmospheric plasma torch fixedly mounted with respect to the electroplating cell. In other words, the plasma torch 22 is fixed with respect to the tank 16 and the anode 14 of the electroplating apparatus 10, and also with respect to the axis of the rotating drum-shaped cathode 12. This corresponds to the configuration of FIG. 1 and FIG. 2.

According to such an embodiment, the plasma generating device, in particular the plasma chamber 24, is mounted on a static support (not shown). The distance D between the outlet of the plasma chamber, through which the generated plasma jet exits the plasma generating device, and the surface of the drum-shaped cathode typically corresponds to a few centimeters, and may be in the range of 1 to 50 cm.

The plasma may be generated using compressed air supplied from bottle 28 through regulator valve 27 at a pressure of 5 bars (in the gas bottle/gas supply reservoir) and with a flow rate of about 1 to 50 L/min to the plasma chamber of the plasma generating device.

Reference sign 23 represents the intersection of the plasma jet with the cathode drum surface; this is the treatment area. The treatment area may thus extend other the whole drum length L and over a width W of e.g. a few cm, the width being defined along a direction tangential to the cathode surface.

For conventional, titanium-made drum-shaped cathode (having a length of about 1 to 2 m, such as 1.5 m and a diameter of about 2 to 3 m such as about 2.7 m), a possible size of the treatment area (i.e. surface of the cathode being exposed to the plasma jet) may be of about L=1.5 m per W=3 cm.

The plasma discharge is generated through application of a power of a few kilowatts to the electrodes (not shown) in the plasma chamber. For such an application, a total power source being typically in the range of 25 kW to 75 kW, in particular about 50 kW, may be desirable.

The plasma ideally contains oxidizing species such as NOx (nitrogen oxides) and hydroxyl radicals.

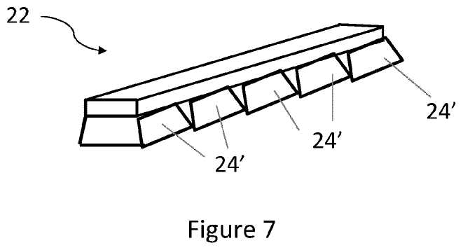

FIG. 7 shows another embodiment, where the plasma generating device comprises an array of plasma chambers 24′. In such case, a number N of plasma chambers 24′ are arranged along the length of the cathode 12 and project N plasma jets (not shown) onto the surface of the cathode. The plasma chambers 24′ do not need to be in strict alignment. What matters is that the N plasma jets form a treatment strip over the length of the cathode, and that after a full revolution of the cathode its whole surface has been treated.

### EXAMPLES

### Removal of Hydride Layer

A first example wherein an atmospheric plasma is used to remove a hydride layer grown onto a titanium surface will now be discussed hereinbelow. The hydride layer is grown on a sample of a titanium foil to simulate the formation of the brown layer on the cathode drum during copper electrolysis.

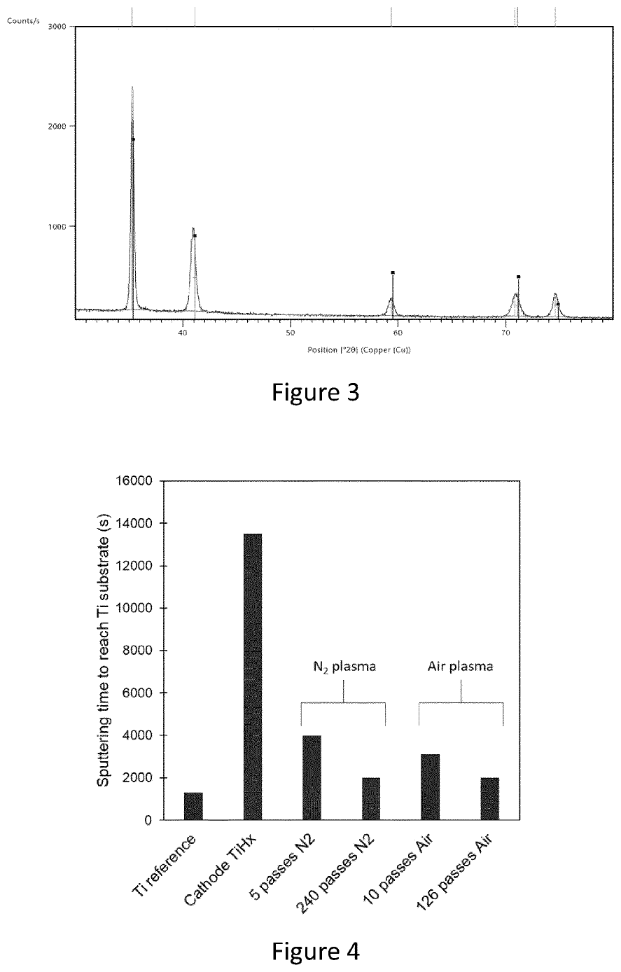

A titanium hydride layer was formed onto the surface of a titanium sample, by immersing the titanium sample in a solution of sulfuric acid at a concentration of 75 g/L and applying a current density of 50 A/dm² thereto during 5 min. It may be noted here that FIG. 3 supports the fact that a hydride layer is formed onto the titanium sample during electroplating.

The sample with the hydride layer was then arranged below a plasma generating device configured as plasma torch and mounted on an industrial robot arm so that the plasma jet outlet (i.e. plasma nozzle) faces the hydride layer on the titanium sample. The plasma nozzle is orientated to irradiate a portion of the surface of the titanium sample, wherein the portion of the surface has a roughly round shape (spot) with a diameter of about 1.5 cm when the nozzle is arranged at a distance of about 1.8 cm from the surface of the titanium sample. Plasma torch reference ULS Omega 1-3 by AcXys Technologies (France) was used. The torch was set to generate plasma having an electron temperature of about 7500 to 8000 K, and preferably a gas temperature of about 500 to 800 K. Temperature was measured using an optical emission spectrometer (OES) equipment.

Compressed air as process gas was fed at a flow of 50 L/min and a pressure of gas inside the gas bottle of 5 to 20 bars to the plasma chamber of the plasma torch and the plasma discharge may be generated with a power of 1000 W.

The plasma torch was moved by the industrial robot arm relative to the surface of the titanium sample at a speed of about 10 mm/s so that the whole surface of the sample was irradiated by the atmospheric plasma jet exiting the outlet of the plasma generating device.

As apparent from FIG. 4, after only 10 passes of the plasma torch, i.e. 10 passes of the plasma jet, the amount of titanium hydride onto the surface of the sample was already strongly reduced, and almost lowered to the reference Ti levels (i.e. level of a reference titanium surface free of titanium hydride) after 126 passes of the plasma torch.

Similar treatment was performed using nitrogen instead of air to produce the plasma jet. Similar results were obtained. As apparent from FIG. 4, after only 5 passes of the plasma torch, i.e. 5 passes of the plasma jet, the amount of titanium hydride onto the surface of the sample was already strongly reduced, and almost lowered to the reference Ti levels (i.e. level of a reference titanium surface free of titanium hydride) after 240 passes of the plasma torch.

Irradiating the surface of a titanium sample presenting a titanium hydride layer by a plasma jet therefore allows removing the hydride layer. Depending on the irradiation time (here represented by the number of passes), the titanium hydride layer can be removed in part or entirely.

### Delaying Formation of Hydride Layer

A second example wherein an atmospheric plasma is used to delay the formation of a hydride layer onto a titanium surface will now be discussed hereinbelow.

A clean (free of hydride layer) titanium foil sample is arranged below a plasma generating device configured as plasma torch mounted on an industrial robot arm so that the plasma jet outlet (i.e. plasma nozzle) faces the titanium sample. The plasma nozzle is configured to irradiate a portion of the surface of the titanium sample, wherein the portion of the surface has a roughly round shape with a diameter of about 1.5 cm when the nozzle is arranged at a distance of about 1.8 cm from the surface of the titanium sample.

Compressed air as process gas may be fed at a flow of 50 L/min and a pressure of gas inside the gas bottle of 5 to 20 bars to the plasma chamber of the plasma torch and the plasma discharge may be generated with a power of 1000 W. The same plasma torch was used as in the first example.

Advantageously, the plasma torch is moved by the industrial robot arm with respect to the surface of the titanium sample at a speed of about 10 mm/s so that the whole surface of the sample is irradiated by the atmospheric plasma jet exiting the outlet of the plasma generating device.

Thirty passes of the plasma torch over the whole surface of the titanium sample are performed to obtain a surface-treated titanium sample.

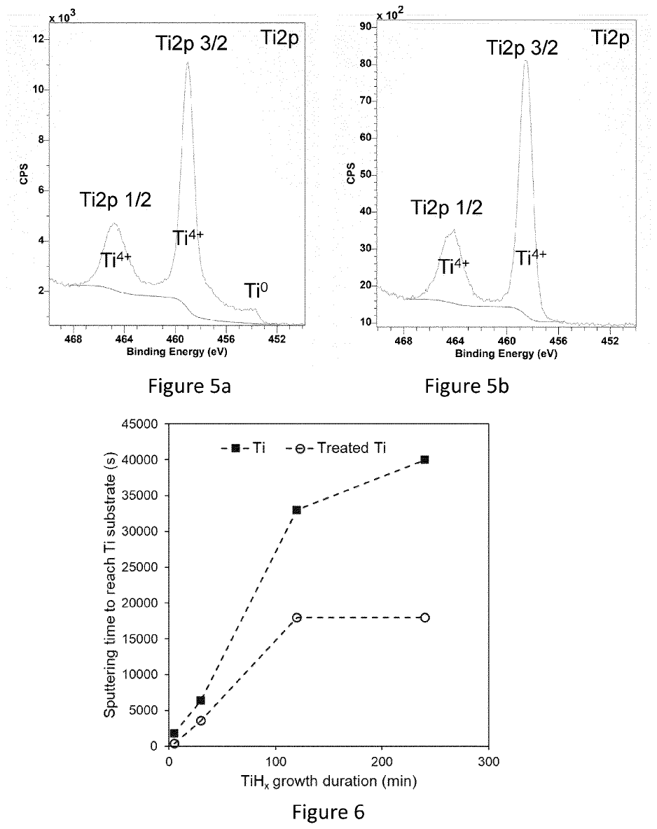

FIG. 5 shows the X-ray photoelectron spectra of the titanium foil surface before (a) and after (b) the 30 passes with the plasma torch. As can be seen, FIG. 5 supports the fact that the surface of the titanium substrate undergoes a treatment by applied the plasma, as the amount of metallic titanium (Ti°) is strongly reduced from FIG. 5a toward FIG. 5b, i.e. upon treatment.

The surface-treated titanium sample is then submitted to the growth (i.e. formation) of a layer of titanium hydride, by immersing the titanium sample in a solution of sulfuric acid at a concentration of 75 g/L and applying a current density of 50 A/dm² thereto for durations ranging from 5 min up to 240 min.

A comparative, untreated titanium sample (i.e. clean titanium foil not subject to 30 passes of plasma torch) is submitted to the same titanium hydride growth conditions to form a layer of titanium hydride over the surface of the titanium sample.

FIG. 6 represents the sputtering time required during ToF-SIMS depth profiling to reach the titanium substrate, for the plasma treated sample (‘Treated Ti’) and for the comparative non plasma treated sample (‘Ti’). As apparent from FIG. 6, the formed hydride layer is always thinner (shorter sputtering time to reach the titanium substrate) on the plasma treated titanium sample than on the untreated, comparative sample. Treating a titanium surface with an atmospheric plasma hence allows to delay the formation of a titanium hydride layer.

1. A method for producing an electrolytic copper foil, comprising
forming a copper foil in an electroplating cell comprising a tank with a copper electrolyte, a rotating cathode drum and an anode, wherein the copper foil is continuously formed on the cathode drum and removed therefrom,
wherein the cathode drum is made of titanium or of a titanium alloy,
wherein performing an anti-hydride treatment step during the production of the copper foil, wherein an atmospheric plasma jet is applied onto the exposed surface of the rotating cathode drum.

2. The method according to claim 1, wherein the plasma jet has an electron temperature comprised between 4000 and 11000 K.

3. The method according to claim 1, wherein the plasma jet is continuously applied onto the exposed surface of the rotating cathode drum during the production of the copper foil.

4. The method according to claim 1, wherein the plasma jet is periodically applied onto the exposed surface of the rotating cathode drum during the production of the copper foil, preferably during about 50 to 75% of production time.

5. The method according to claim 1, wherein the plasma jet is generated by an atmospheric plasma generating device from a process gas comprising at least 60%-vol of nitrogen.

6. The method according to claim 5, wherein the process gas is air, preferably supplied at a flow rate of between 1 and 1000 L/min to the plasma generating device.

7. The method according to claim 1, wherein the plasma jet comprises nitrogen, oxygen and hydrogen,

8. The method according to claim 1, wherein plasma jet is generated by a discharge generated with a total power of 25000 to 75000 W.

9. The method according to claim 1, wherein the plasma jet is generated by a plasma generating device mounted on a mobile support configured to move the plasma generating device relative to the cathode and the plasma jet is continuously scanned over the exposed surface of the cathode drum.

10. (canceled)

11. The method according to claim 1, wherein the plasma jet is generated by a plasma jet generating device fixedly mounted with respect to the electroplating cell.

12. (canceled)

13. (canceled)

14. The method according to claim 1, wherein a distance between an outlet of the plasma generating device, through which the plasma jet is ejected, and the surface of the cathode drum is between 1 and 20 cm.

15. The method according to claim 1, wherein the method is implemented to remove and/or prevent hydrogen corrosion on the cathode drum, wherein a surface of the cathode drum is irradiated in an open-air environment with the plasma jet that is produced by the plasma generating device.

16. An electroplating apparatus, in particular configured for performing a method producing an electrolytic copper foil, comprising
forming a copper foil in an electroplating cell comprising a tank with a copper electrolyte, a rotating cathode drum and an anode, wherein the copper foil is continuously formed on the cathode drum and removed therefrom,
wherein the cathode drum is made of titanium or of a titanium alloy,
wherein performing an anti-hydride treatment step during the production of the copper foil, wherein an atmospheric plasma jet is applied onto the exposed surface of the rotating cathode drum, wherein the apparatus comprises:
a metallic drum-shaped rotating cathode made of titanium or of a titanium alloy;
a stationary anode;
a tank for an electrolyte, wherein the drum-shaped cathode and the anode are arranged spaced apart from each other in the tank; and
a plasma generating device configured to generate an atmospheric plasma in a plasma chamber, the plasma chamber having an outlet facing the drum-shaped cathode such that a plasma jet irradiates at least a portion of a surface of the drum-shaped cathode to treat the latter against hydride corrosion.

17. The electroplating apparatus according to claim 16, wherein the plasma generating device comprises a process gas inlet to said plasma chamber and at least one pair of electrodes to create a discharge.

18. The electroplating apparatus according to claim 16, wherein the plasma chamber is designed as a plasma torch.

19. The electroplating apparatus according to claim 16, wherein the plasma jet has an electron temperature comprised between 4000 and 11000 K.

20. The electroplating apparatus according to claim 16, wherein the plasma jet is generated in the plasma chamber from process gas comprising at least 60 %-vol of nitrogen.

21. The electroplating apparatus according to claim 16, wherein the plasma chamber is configured to extend over the whole length of the cathode.

22. The electroplating apparatus according to claim 16, wherein the plasma generating device comprises an array of plasma chambers, the latter being arranged to project plasma jets over the length of the cathode.

23. The electroplating apparatus according to claim 16. wherein a distance between the outlet and the surface of the cathode lies between 1 and 20 cm.

24. The electroplating apparatus according to claim 16, wherein the plasma generating device is fixedly mounted with respect to the tank/anode.

25. (canceled)

26. (canceled)

27. The electroplating apparatus according to claim 16, wherein the plasma generating device is mounted on a mobile support configured to move the plasma chamber relative to the drum-shaped cathode.

28. The electroplating apparatus according to claim 27, wherein the discharge is generated with a total power of 25000 to 75000 W.
